(19) United States
(12) Patent Application Publication
(10) Pub. No.: US 2009/0073349 A1
(43) Pub. Date: Mar. 19, 2009

(54) THREE-DIMENSIONAL MICROFABRICATION METHOD USING PHOTOSENSITIVE NANOCRYSTALS AND DISPLAY DEVICE

(75) Inventors: Jong Jin PARK, Yongin-si (KR); Sung Woong KIM, Suwon-si (KR); Tae Woon CHA, Seoul (KR); Eun Joo JANG, Suwon-si (KR)

Correspondence Address: CANTOR COLBURN, LLP, 20 Church Street, 22nd Floor, Hartford, CT, 06103, US

(73) Assignee: Samsung Electronics Co., Ltd., Suwon-si (KR)

(21) Appl. No.: 12/050,650

(22) Filed: Mar. 18, 2008

(30) Foreign Application Priority Data
Sep. 17, 2007 (KR) 10-2007-94080

(51) Int. Cl. G02F 1/1335; G03F 7/00

(52) U.S. Cl. 349/69; 430/311

(57) ABSTRACT

Example embodiments provide a three-dimensional microfabrication method using photosensitive nanocrystals is provided. The method comprises the steps of preparing a photosensitive composition comprising a photocurable compound and nanocrystals whose surface is coordinated with a compound having a photosensitive group, applying the photosensitive composition to a substrate and drying the photosensitive composition to form a thin film, and subjecting the thin film to three-dimensional microfabrication. According to the method, nanocrystals are arranged in a three-dimensional array to form photonic crystals or a three-dimensional structure. The three-dimensional structure can be used for the fabrication of micro-electro-mechanical systems (MEMS), thus contributing to the manufacture of display devices and electronic devices on a nanometer scale. Example embodiments also provide a display device using the three-dimensional structure of nanocrystals.

### PRIORITY STATEMENT

This application claims priority under U.S.C. § 119 to Korean Patent Application No. 10-2007-94080, filed on Sep. 17, 2007, in the Korean Intellectual Property Office (KIPO), the entire contents of which are incorporated herein by reference.

### BACKGROUND

1. Field

Example embodiments relate to a three-dimensional microfabrication method using photosensitive nanocrystals and a display device. Other example embodiments relate to a three-dimensional microfabrication method using photosensitive nanocrystals wherein a photosensitive composition comprising a photocurable compound and semiconductor nanocrystals whose surface is coordinated with a compound having a photosensitive group is used to form a thin film of the nanocrystals, followed by three-dimensional microfabrication to form a three-dimensional structure of the nanocrystals with high precision in a simple manner, and a display device using a three-dimensional structure of nanocrystals formed by the method.

2. Description of the Related Art

A nanocrystal is a crystalline material having a size of a few nanometers and consists of several hundred to several thousand atoms. Since a nanocrystal has a large surface area per unit volume, most of the constituent atoms of the nanocrystal are present at the surface of the nanocrystal and unexpected characteristics (e.g., quantum confinement effects) of the nanocrystal are exhibited. These structural characteristics account for unique electrical, magnetic, optical, chemical and mechanical properties of nanocrystals different from those inherent to the constituent atoms of the nanocrystals.

The luminescent properties and electrical properties of semiconductor nanocrystals can be controlled, for example, by varying the size and composition of the semiconductor nanocrystals. Therefore, semiconductor nanocrystals can find application in various industrial fields, including light-emitting devices (e.g., light-emitting diodes (LEDs), electroluminescent (EL) devices, laser devices, holographic devices and sensors) and electronic devices (e.g., solar cells, photodetectors and transistors). Two- or three-dimensional arrangement of nanocrystals is needed to use the nanocrystals in various applications. Attempts to effectively arrange nanocrystals in a three-dimensional array have not been successful.

Patterning techniques of nanocrystals reported hitherto are mainly associated with the patterning of quantum dots by vapor deposition, require the use of expensive systems, and involve high-temperature processing. According to other conventional methods, nanocrystals are mixed with a photosensitive material, followed by lithography to form a two-dimensional pattern. A disadvantage of the methods is that the nanocrystals are separated from the photosensitive material or are used in limited amounts.

### SUMMARY

Accordingly, example embodiments have been made to provide a microfabrication method using photosensitive nanocrystals by which a three-dimensional structure of nanocrystals can be formed, and a display device that achieves high luminance, low power consumption and cost effectiveness using various light sources without a color filter.

Example embodiments provide a three-dimensional microfabrication method using photosensitive nanocrystals, the method comprising the steps of: preparing a photosensitive composition comprising a photocurable compound and nanocrystals whose surface is coordinated with a compound having a photosensitive group; applying the photosensitive composition to a substrate to form a thin film; and subjecting the thin film to three-dimensional microfabrication.

The three-dimensional microfabrication step may be carried out by nano-imprint lithography, microcontact printing, replica molding, microtransfer molding, microstereolithography, etc.

Example embodiments also provide a display device comprising a display unit wherein the display unit includes a three-dimensional structure of nanocrystals whose surface is coordinated with a photosensitive compound to produce two or more different colors.

### BRIEF DESCRIPTION OF THE DRAWINGS

Example embodiments will be more clearly understood from the following detailed description taken in conjunction with the accompanying drawings. FIGS. 1-6 represent non-limiting, example embodiments as described herein.

FIG. 1 is a schematic diagram of a semiconductor nanocrystal whose surface is coordinated with a compound having a photosensitive group, which is used in a method of example embodiments.

FIGS. 2, 3 and 4 are photographs of three-dimensional structures formed in Examples 1, 2 and 3, respectively.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Hereinafter, example embodiments will be described in detail with reference to the attached drawings. Reference now should be made to the drawings, in which the same reference numerals are used throughout the different drawings to designate the same or similar components. In the drawings, the thicknesses and widths of layers are exaggerated for clarity. Example embodiments may, however, be embodied in many different forms and should not be construed as limited to the example embodiments set forth herein. Rather, these example embodiments are provided so that this disclosure will be thorough and complete, and will fully convey the scope of example embodiments to those skilled in the art.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The term “microfabrication” as used herein is a concept that includes micromachining, bulk micromachining, nanomachining, laser micromachining, etc., which are techniques employed to construct nanometer-sized materials and structures.

The expression “three-dimensional structure of nanocrystals” as used herein refers to a three-dimensional structure on a micrometer or nanometer scale that includes any structure comprising light-emitting nanocrystals (also termed ‘quantum dots’).

The three-dimensional microfabrication method of example embodiments is characterized in that a three-dimensional structure of nanocrystals is formed using photosensitive semiconductor nanocrystals including semiconductor nanocrystals and a photosensitive compound coordinated to the surface of the semiconductor nanocrystals. The three-dimensional structure of nanocrystals is formed by the following procedure. First, a photosensitive composition comprising a photocurable compound and nanocrystals whose surface is coordinated (hereinafter, abbreviated to ‘surface-coordinated’) with a compound having a photosensitive group (hereinafter, referred to as simply a ‘photosensitive compound’) is prepared. Subsequently, the photosensitive composition is applied to a substrate and dried to form a thin film of the nanocrystals. Thereafter, the thin film is subjected to three-dimensional microfabrication to form the final three-dimensional structure of the nanocrystals.

A more detailed explanation of the respective steps of the method according to example embodiments will be provided below.

(i) Preparation of Photosensitive Composition

A photosensitive composition comprising semiconductor nanocrystals surface-coordinated with a photosensitive compound and a polymer or ester compound having at least one acryl or vinyl group as a photocurable compound is prepared. Any common semiconductor nanocrystals may be used instead of the photosensitive semiconductor nanocrystals. The photosensitive composition may further comprise a photoinitiator and a two-photon absorbing compound.

According to the method of example embodiments, the nanocrystals surface-coordinated with the photosensitive compound is directly reacted with a laser beam from a light source to induce high-density three-dimensional patterning. Therefore, the method of example embodiments is advantageous in terms of three-dimensional microfabrication efficiency over conventional methods in which nanocrystals are simply blended with a photosensitive mixture. In addition, the mixing ratio of the nanocrystals in a three-dimensional structure of nanocrystals formed by the method of example embodiments is increased, thus contributing to an improvement in luminescence efficiency.

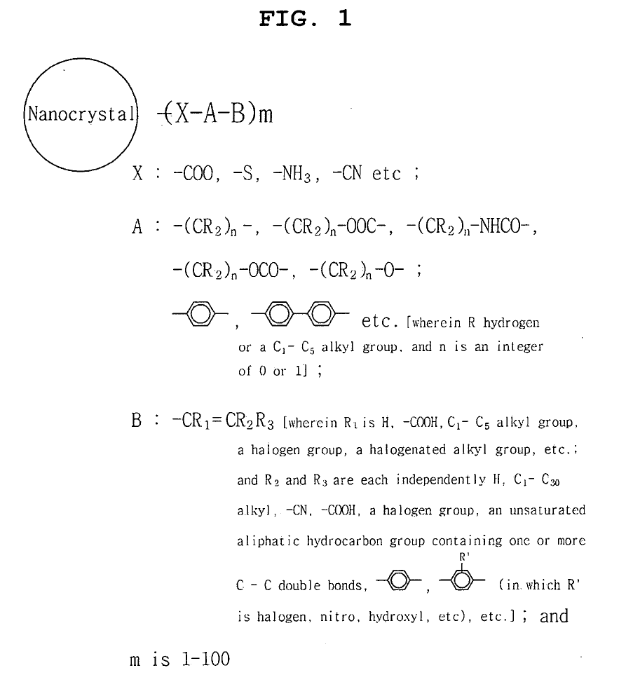

FIG. 1 is a schematic diagram of a photosensitive semiconductor nanocrystal according to a preferred embodiment of example embodiments. In FIG. 1, X is a linker that plays a role in binding the semiconductor nanocrystal to a photosensitive group, such as an acryl or vinyl group. The surface-coordinating degree of the photosensitive compound to the surface of the semiconductor nanocrystal can be appropriately controlled by varying the mixing ratio between the nanocrystal and the photosensitive compound. The semiconductor nanocrystals used in example embodiments have a diameter ranging from about 1 to about 10 nm. Various factors (e.g., composition and size) of the semiconductor nanocrystals can be varied to achieve light emission at a desired wavelength. That is, light of various wavelengths, including blue, green and red light, can be easily realized from the semiconductor nanocrystals.

All semiconductor nanocrystals that can be prepared by wet chemistry methods can be used in example embodiments. For example, the semiconductor nanocrystals used in example embodiments may be prepared by adding a corresponding metal precursor to an organic solvent in the absence or presence of a dispersant and growing the metal precursor into a crystal at a particular temperature.

The nanocrystals used in example embodiments may be those composed of metal oxides. Examples of such metal oxide nanocrystals include, but are not necessarily limited to, TiO₂, ZnO, SiO₂, SnO₂, WO₃, Ta₂O₃, BaTiO₃, BaZrO₃, ZrO₂, HfO₂, Al₂O₃, Y₂O₃, ZrSiO₄, Fe₂O₃, Fe₃O₄, CeO, CrO₃ and mixtures thereof.

Examples of suitable semiconductor nanocrystals for use in example embodiments include Group II-VI, Group III-V, Group IV-VI, Group IV compounds, and mixtures thereof.

Specifically, the Group II-VI compounds are selected from the group consisting of, but not necessarily limited to: binary compounds, e.g., CdSe, CdTe, ZnS, ZnSe, ZnTe, ZnO, HgS, HgSe and HgTe; ternary compounds, e.g., CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS and HgZnSe; and quaternary compounds, e.g., CdZnSeS, CdZnSeTe, CdZnSTe, CdHgSeS, CdHgSeTe, CdHgSTe, HgZnSeS, HgZnSeTe and HgZnSTe.

The Group III-V compounds are selected from the group consisting of, but not necessarily limited to: binary compounds, e.g., GaN, GaP, GaAs, GaSb, AlN, AlP, AlAs, AlSb, InN, InP, InAs and InSb; ternary compounds, e.g., GaNP, GaNAs, GaNSb, GaPAs, GaPSb, AlNP, AlNAs, AlNSb, AlPAs, AlPSb, InNP, InNAs, InNSb, InPAs, InPSb and GaAlNP; and quaternary compounds, e.g., GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb.

The Group IV-VI compounds are selected from the group consisting of, but not necessarily limited to: binary compounds, e.g., SnS, SnSe, SnTe, PbS, PbSe and PbTe; ternary compounds, e.g., SnSeS, SnSeTe, SnSTe, PbSeS, PbSeTe, PbSTe, SnPbS, SnPbSe and SnPbTe; and quaternary compounds, e.g., SnPbSSe, SnPbSeTe and SnPbSTe.

The Group IV compounds are selected from the group consisting of, but not necessarily limited to: unary compounds, e.g., Si and Ge; and binary compounds, e.g., SiC and SiGe.

The semiconductor nanocrystals may further include an overcoating to form a core-shell structure. The overcoating may be formed of a compound selected from Group II-VI compounds, Group III-V compounds, Group IV-VI compounds, Group IV compounds, and mixtures thereof.

Specifically, the Group II-VI compounds can be selected from the group consisting of binary compounds, e.g., CdS, CdSe, CdTe, ZnS, ZnSe, ZnTe, ZnO, HgS, HgSe and HgTe, ternary compounds, e.g., CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS and HgZnSe, and quaternary compounds, e.g., CdZnSeS, CdZnSeTe, CdZnSTe, CdHgSeS, CdHgSeTe, CdHgSTe, HgZnSeS, HgZnSeTe and HgZnSTe. The Group III-V compounds can be selected from the group consisting of binary compounds, e.g., GaN, GaP, GaAs, GaSb, AlN, AlP, AlAs, AlSb, InN, InP, InAs and InSb, ternary compounds, e.g., GaNP, GaNAs, GaNSb, GaPAs, GaPSb, AlNP, AlNAs, AlNSb, AlPAs, AlPSb, InNP, InNAs, InNSb, InPAs, InPSb, GaAlNP, AlGaN, AlGaP, AlGaAs, AlGaSb, InGaN, InGaP, InGaAs, InGaSb, AlInN, AlInP, AlInAs and AlInSb, and quaternary compounds, e.g., GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb. The Group IV-VI compounds can be selected from the group consisting of binary compounds, e.g., SnS, SnSe, SnTe, PbS, PbSe and PbTe, ternary compounds, e.g., SnSeS, SnSeTe, SnSTe, PbSeS, PbSeTe, PbSTe, SnPbS, SnPbSe and SnPbTe, and quaternary compounds, e.g., SnPbSSe, SnPbSeTe and SnPbSTe. The Group IV compounds can be selected from the group consisting of unary compounds, e.g., Si and Ge, and binary compounds, e.g., SiC and SiGe.

The semiconductor nanocrystals may have a multilayer structure consisting of two or more layers, each layer being composed of two different kinds of materials. The multilayer structure of the semiconductor nanocrystals may comprise one or more alloy interlayers, each being composed of different materials constituting the adjacent layers, at the interfaces between the respective layers. The alloy interlayers may be composed of a gradient alloy having a composition gradient of the materials.

In the photosensitive compound coordinated to the surface of the semiconductor nanocrystals, a photosensitive group (e.g., a carbon-carbon double bond or an acryl group) is directly bonded to a linker (e.g., cyanide, thiol (SH), amine, carboxyl or phosphonic acid group) or is bonded to the linker through alkylene, amide, phenylene, biphenylene, ester or ether group.

Preferably, the photosensitive compound is represented by Formula 1:

X-A-B (1)

wherein X is NC—, HOOC—, HRN—, POOOH—, RS— or RSS— (in which R is hydrogen or a C₁-C₁₀ saturated or unsaturated aliphatic hydrocarbon group); A is a direct bond, an aliphatic organic group, a phenylene group or a biphenylene group; and B is an organic group containing one or more carbon-carbon double bonds which may be interrupted or terminated by at least one group selected from —CN, —COOH, halogen groups, C₁-C₅ halogenated alkyl groups, amine groups, C₆-C₁₅ aromatic hydrocarbon groups, and C₆-C₁₂ aromatic hydrocarbon groups substituted with F, Cl, Br, a halogenated alkyl group, R′O— (in which R′ is hydrogen or C₁-C₅ alkyl), —COOH, an amine group or —NO₂.

More preferably, the aliphatic organic group of A in Formula 1 is a saturated aliphatic hydrocarbon group, such as —(CR₂)ₙ— (in which R is hydrogen, a C₁-C₅ alkyl group, and n is an integer from 1 to 30), an aliphatic ester group containing an ester moiety (—COO—), an aliphatic amide group containing an amide moiety (—NHCO—), an aliphatic oxycarbonyl group containing an oxycarbonyl moiety (—OCO—), or an aliphatic ether group containing an ether moiety (—O—). The aliphatic organic group may be substituted with a C₁-C₅ alkyl group or interrupted by a hydroxyl, amine or thiol group.

In Formula 1, B is preferably an organic group represented by Formula 2:

—CR₁═CR₂R₃ (2)

wherein R₁ is hydrogen, —COOH, a halogen group, a C₁-C₅ alkyl group or a halogenated alkyl group; and R₂ and R₃ are each independently hydrogen, a C₁-C₃₀ alkyl group, —CN, —COOH, a halogen group, a C₁-C₅ halogenated alkyl group, a C₂-C₃₀ unsaturated aliphatic hydrocarbon group containing one or more carbon-carbon double bonds, or a C₆-C₁₂ aromatic hydrocarbon group substituted or unsubstituted with at least one group selected from F, Cl, Br, hydroxyl, C₁-C₅ halogenated alkyl groups, amine groups, R′O— (in which R′ is C₁-C₅ alkyl), —COOH and —NO₂.

In R₂ and R₃ of Formula 2, the C₁-C₃₀ alkyl group or the C₂-C₃₀ unsaturated aliphatic hydrocarbon group containing at least one or more carbon-carbon double bonds may be substituted with an alkyl group, and if necessary, may be interrupted or terminated by a hydroxyl group, a carboxyl group, etc. The number of the double bonds in the unsaturated aliphatic hydrocarbon group is not especially limited, but is preferably not greater than 3.

Non-limiting examples of the photosensitive compound of Formula 1 include, but are not necessarily limited to, acid compounds, such as acrylic acids, unsaturated fatty acids, cinnamic acids and vinyl benzoic acids, acrylonitrile compounds, unsaturated nitrile compounds, unsaturated amine compounds, unsaturated sulfide compounds, and mixtures thereof.

Specific examples of the compound of Formula 1 include methacrylic acid, crotonic acid, vinylacetic acid, tiglic acid, 3,3-dimethylacrylic acid, trans-2-pentenoic acid, 4-pentenoic acid, trans-2-methyl-2-pentenoic acid, 2,2-dimethyl-4-pentenoic acid, trans-2-hexenoic acid, trans-3-hexenoic acid, 2-ethyl-2-hexenoic acid, 6-heptenoic acid, 2-octenoic acid, citronellic acid, undecylenic acid, myristoleic acid, palmitoleic acid, oleic acid, elaidic acid, cis-11-elcosenoic acid, euric acid, nervonic acid, trans-2,4-pentadienoic acid, 2,4-hexadienoic acid, 2,6-heptadienoic acid, geranic acid, linoleic acid, 11,14-eicosadienoic acid, cis-8,11,14-eicosatrienoic acid, arachidonic acid, cis-5,8,11,14,17-eicosapentaenoic acid, cis-4,7,10,13,16,19-docosahexaenoic acid, fumaric acid, maleic acid, itaconic acid, citraconic acid, mesaconic acid, trans-glutaconic acid, trans-beta-hydromuconic acid, trans-traumatic acid, trans-muconic acid, cis-aconitic acid, trans-aconitic acid, cis-3-chloroacrylic acid, trans-3-chloroacrylic acid, 2-bromoacrylic acid, 2-(trifluoromethyl)acrylic acid, trans-styrylacetic acid, trans-cinnamic acid, alpha-methylcinnamic acid, 2-methylcinnamic acid, 2-fluorocinnamic acid, 2-(trifluoromethyl)cinnamic acid, 2-chlorocinnamic acid, 2-methoxycinnamic acid, 2-hydroxycinnamic acid, 2-nitrocinnamic acid, 2-carboxycinnamic acid, trans-3-fluorocinnamic acid, 3-(trifluoromethyl)cinnamic acid, 3-chlorocinnamic acid, 3-bromocinnamic acid, 3-methoxycinnamic acid, 3-hydroxycinnamic acid, 3-nitrocinnamic acid, 4-methylcinnamic acid, 4-fluorocinnamic acid, trans-4-(trifluoromethyl)-cinnamic acid, 4-chlorocinnamic acid, 4-bromocinnamic acid, 4-methoxycinnamic acid, 4-hydroxycinnamic acid, 4-nitrocinnamic acid, 3,3-dimethoxycinnamic acid, 4-vinylbenzoic acid, allyl methyl sulfide, allyl disulfide, diallylamine, oleylamine, 3-amino-1-propanol vinyl ether, 4-chlorocinnamonitrile, 4-methoxycinnamonitrile, 3,4-dimethoxycinnamonitrile, 4-dimethylaminocinnamonitrile, acrylonitrile, allyl cyanide, crotononitrile, methacrylonitrile, cis-2-pentenenitrile, trans-3-pentenenitrile, 3,7-dimethyl-2,6-octadienenitrile, 1,4-dicyano-2-butene, and mixtures thereof.

The photosensitive semiconductor nanocrystals may be prepared by growing desired nanocrystals from a corresponding metal precursor, dispersing the nanocrystals in an organic solvent, and treating the nanocrystals with the photosensitive compound of Formula 1. For example, the treatment of the nanocrystals can be performed by refluxing the dispersion of the nanocrystals in the presence of the photosensitive compound. The treatment conditions, e.g., reflux time and temperature and the concentration of the photosensitive compound, can be properly selected according to the kind of the photosensitive compound coordinated to the surface of the nanocrystals, the dispersion medium and the nanocrystals. Specifically, nanocrystals are surface-coordinated with a dispersant (e.g., mercaptopropanol) having a reactive end group and reacted with a photosensitive compound (e.g., methacryloyl chloride) capable of reacting with the reactive end group to prepare nanocrystals surface-coordinated with the photosensitive compound.

Alternatively, semiconductor nanocrystals may be directly surface-coordinated with a photosensitive compound by adding a corresponding metal precursor into an organic solvent and growing the metal precursor into crystals at a predetermined temperature in the presence of a photosensitive compound. The kind of the organic solvent, the temperature for crystal growth and the concentration of the metal precursor can be appropriately varied depending on the kind of the photosensitive compound and the kind, size and shape of the desired semiconductor nanocrystals.

The photocurable compound used in the photosensitive composition is preferably a polyfunctional acrylate or polyalkylene oxide compound having two or more acryl and/or vinyl groups, or a monomer having one or more acryl and/or vinyl groups.

Examples of preferred photocurable compounds for use in example embodiments include, but are not necessarily limited to, allyloxylated cyclohexyl diacrylate, bis(acryloxyethyl)hydroxy isocyanurate, bis(acryloxyneopentyl glycol)adipate, bisphenol. A diacrylate, bisphenol A dimethacrylate, 1,4-butanediol diacrylate, 1,4-butanediol dimethacrylate, 1,3-butylene glycol diacrylate, 1,3-butylene glycol dimethacrylate, dicyclopentanyl diacrylate, diethylene glycol diacrylate, diethylene glycol dimethacrylate, dipentaerythritol hexaacrylate, dipentaerythritol monohydroxypentacrylate, ditrimethylolpropane tetraacrylate, ethylene glycol dimethacrylate, glycerol methacrylate, 1,6-hexanediol diacrylate, neopentyl glycol dimethacrylate, neopentyl glycol hydroxypivalate diacrylate, pentaerythritol triacrylate, pentaerythritol tetraacrylate, phosphoric acid dimethacrylate, polyethylene glycol diacrylate, polypropylene glycol diacrylate, tetraethylene glycol diacrylate, tetrabromobisphenol A diacrylate, triethylene glycol divinyl ether, triglycerol diacrylate, trimethylolpropane triacrylate, tripropylene glycol diacrylate, tris(acryloxyethyl)isocyanurate, phosphoric acid triacrylate, phosphoric acid diacrylate, acrylic acid propargyl ester, vinyl terminated polydimethylsiloxane, vinyl terminated diphenylsiloxane-dimethylsiloxane copolymer, vinyl terminated polyphenylmethylsiloxane, vinyl terminated trifluoromethylsiloxane-dimethylsiloxane copolymer, vinyl terminated diethylsiloxane-dimethylsiloxane copolymer, vinylmethylsiloxane, monomethacryloyloxypropyl terminated polydimethyl siloxane, monovinyl terminated polydimethyl siloxane, monoallyl-monotrimethylsiloxy terminated polyethylene oxide, and mixtures thereof.

The composition ratio between the photosensitive semiconductor nanocrystals and the photocurable compound is not especially restricted and may be suitably selected taking into consideration the photocurability (e.g., curing rate and state of a cured film to be formed) and the ability of the photosensitive compound to be coordinated to the nanocrystals.

The photosensitive composition used in example embodiments may further comprise a photoinitiator and a two-photon absorbing compound.

According to the method of example embodiments, the photosensitive semiconductor nanocrystals or the photosensitive composition may undergo a crosslinking reaction upon exposure to light even in the absence of a photoinitiator to form a pattern, unlike in common photolithographic processes. If needed, a photoinitiator may be used to assist the crosslinking reaction.

Any known initiator capable of generating free radicals upon light irradiation can be used in example embodiments, and preferred examples thereof include acetophenone, benzoin, benzophenone, thioxanthone and triazine compounds.

Specific examples of acetophenone compounds as photopolymerization initiators include 2,2′-diethoxyacetophenone, 2,2′-dibutoxyacetophenone, 2-hydroxy-2-methylpropiophenone, p-t-butyltrichloroacetophenone, p-t-butyldichloroacetophenone, benzophenone, 4-chloroacetophenone, 4,4′-dimethylaminobenzophenone, 4,4′-dichlorobenzophenone, 3,3′-dimethyl-2-methoxybenzophenone, 2,2′-dichloro-4-phenoxyacetophenone, 2-methyl-1-(4-(methylthio)phenyl)-2-morpholinopropan-1-one, 1,2-octanedione-1-[4-(phenylthio)phenyl]-2-(o-benzoyloxime), and 2-benzyl-2-dimethylamino-1-(4-morpholinophenyl)-butan-1-one.

Examples of suitable benzophenone compounds include benzophenone, benzoyl benzoic acid, methyl benzoyl benzoate, 4-phenyl benzophenone, hydroxybenzophenone, acrylated benzophenone, 4,4′-bis(dimethylamino)benzophenone, and 4,4′-bis(diethylamino)benzophenone.

Examples of suitable thioxanthone compounds include thioxanthone, 2-chlorothioxanthone, 2-methylthioxanthone, isopropylthioxanthone, 1-[9-ethyl-6]-(2-methylbenzoyl)-9H-carbazol-3-yl]-1-(O-acetyloxime), 2,4-diethylthioxanthone, 2,4-diisopropylthioxanthone, and 2-chlorothioxanthone.

Examples of suitable benzoin compounds include benzoin, benzoin methyl ether, benzoin ethyl ether, benzoin isopropyl ether, benzoin isobutyl ether, and benzyl dimethyl ketal.

Examples of suitable triazine compounds include 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-styryl)-4,6-bis(trichloromethyl)-s-triazine, 2-biphenyl-4,6-bis(trichloromethyl)-s-triazine, bis(trichloromethyl)-6-styryl-s-triazine, 2-(naphtho-1-yl)-4,6-bis(trichloromethyl)-s-triazine, 2-(4-methoxynaphtho-1-yl)-4,6-bis(trichloromethyl)-s-triazine, 2-4-trichloromethyl(piperonyl)-s-triazine, and 2-4-trichloromethyl(4′-methoxystyryl)-s-triazine. Other photoinitiators include carbazole, diketone, sulfonium borate, diazo, biimidazole, pyrilium, organic peroxide, sulfonium, iodonium and mercapto compounds.

The photosensitive composition may further comprise a two-photon absorbing compound. A new concept of technology is required to ensure a precision in three-dimensional microfabrication on a sub-micron level. Curing phenomenon based on two-photon absorption can be utilized to form a three-dimensional structure with a precision below the diffraction limit of light. One-photon absorption increases or decreases linearly depending on the intensity of incident light, whereas the probability of the absorption of two photons has a quadratic dependence on the intensity of incident light. The number of photons absorbed increases as the intensity of incident light increases. Since two-photon absorption is less reduced than one-photon absorption within a curable composition, molecules present in deeper positions of the material can be selectively excited using a depth-focused light source, thus enabling the formation of a three-dimensional structure with a high spatial resolution. According to the curing phenomenon based on two-photon absorption, only portions having a very high peak power of laser light receive and absorb two-photon energy. Accordingly, the two-photon absorption is utilized to cure only portions around the focal points of laser light, and as a result, a precision on the order of tens of nanometers can be achieved.

A typical two-photon absorbing compound includes both a polymerizable moiety (Y) and a two-photon absorbing moiety (X). The moiety (X) may have a structure of the following three structures:

(1) An electron donor—a n-electron center—an electron donor;

(2) An electron donor—a n-electron center—an electron acceptor; and

(3) An electron acceptor—a n-electron center—an electron acceptor.

For example, the electron donor may be an ether, thiol or amine group, and the electron acceptor may be a nitrile or carbonyl group. The n-electron center may be selected from combined structures of benzene, thiophene, stilbene and azo units.

The moiety (X) may be prepared by addition polymerization of an unsaturated vinyl monomer (e.g., a styrene, acryl or methacryl monomer), a bicyclic monomer capable of being polymerized by ring-opening, etc.

The moiety (X) has a sandwich structure in which a n-electron center, i.e. an aromatic system or a conjugated unsaturated hydrocarbon system, acting as a bridge for electron transfer is substituted with an electron donor and/or an electron acceptor. Examples of suitable two-photon absorbing materials for use in example embodiments include the following compounds (3):

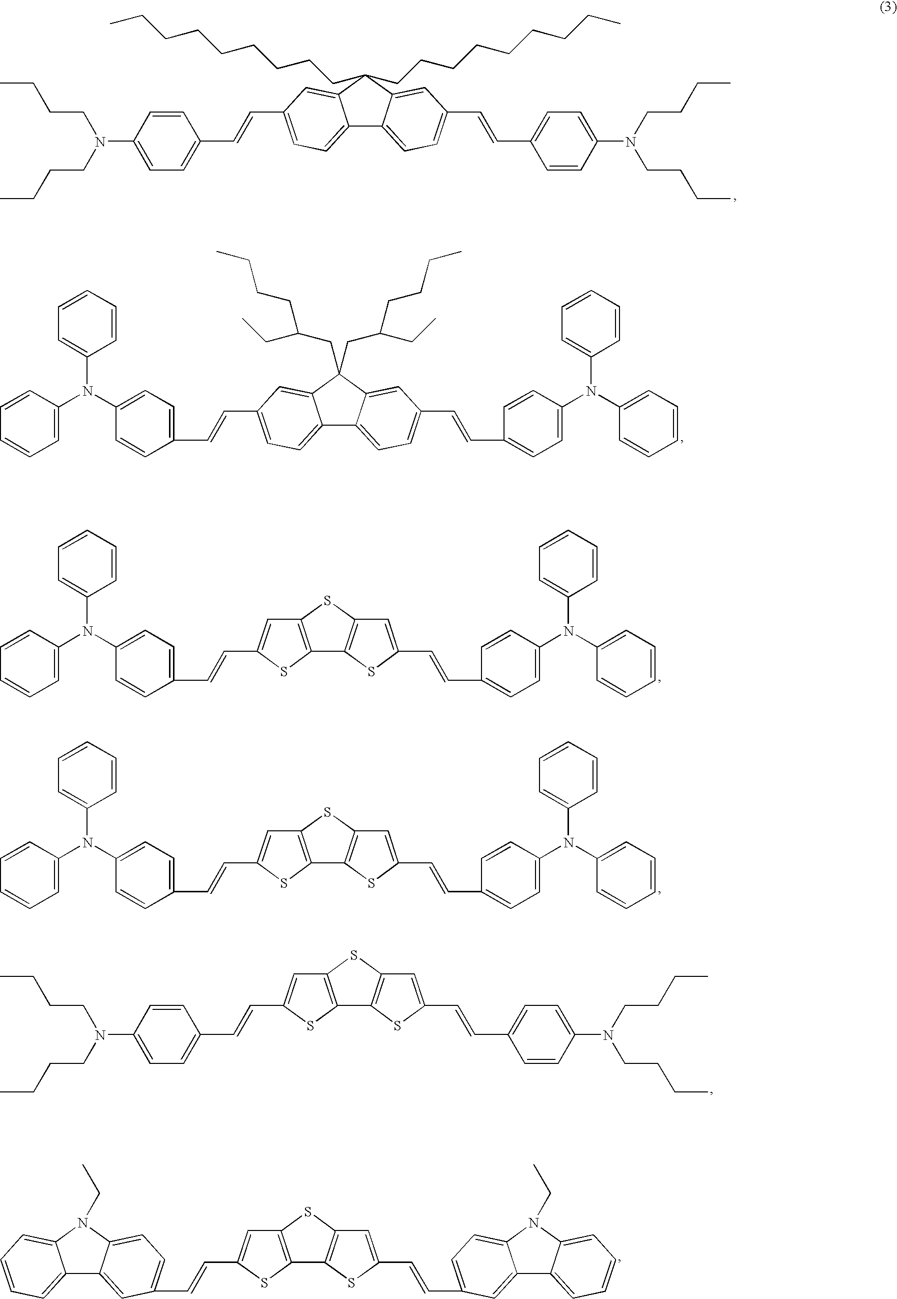

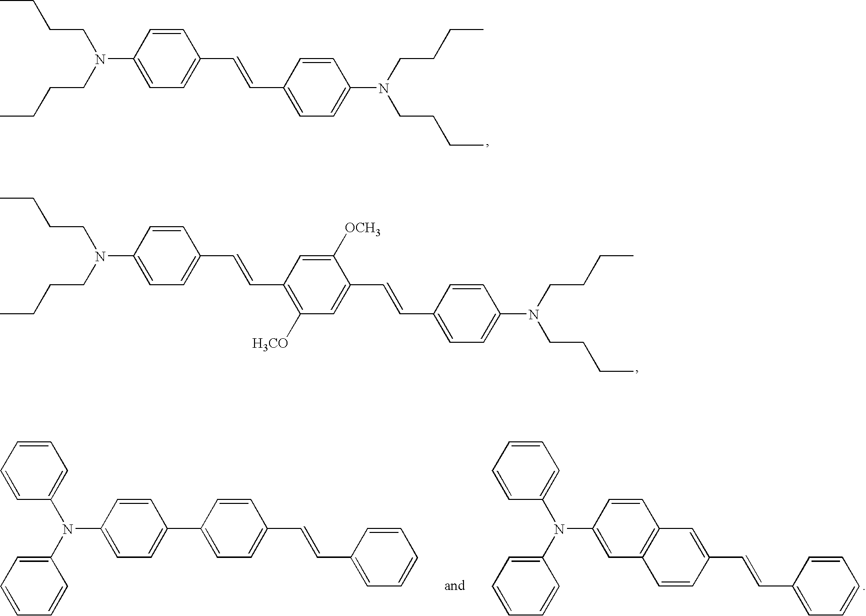

These two-photon absorbing dyes simultaneously absorb two photons to release energy two times higher than that of one-photon absorption, so that they can effectively excite photosensitive molecules in the course of the two-photon absorption.

The composition for the formation of a three-dimensional structure of the nanocrystals according to example embodiments may comprise 0.1 to 10% by weight of a combination of the two-photon absorption (TPA) material, the photoinitiator and a photosensitizer.

If necessary, the photosensitive composition may further comprise a solvent for viscosity adjustment. Specific examples of the solvent include, but are not necessarily limited to, ethylene glycol acetate, ethyl cellosolve, propylene glycol methyl ether acetate, ethyl lactate, polyethylene glycol, cyclohexanone, and propylene glycol methyl ether. These solvents can be used alone or as a mixture thereof.

(ii) Formation of Thin Film of the Photosensitive Composition

In this step, the photosensitive composition is applied to a substrate and dried to form a thin film. Specifically, the photosensitive semiconductor nanocrystals and the photocurable compound are dispersed in an organic solvent and applied to a substrate to form a film of the semiconductor nanocrystals. There is no particular limitation on the thickness of the thin film.

Any solvent that can homogeneously disperse the nanocrystals and be readily removed after application may be used without any particular limitation in example embodiments, and examples thereof include DMF, 4-hydroxy-4-methyl-2-pentanone, ethylene glycol monoethyl ether, 2-methoxyethanol, chloroform, chlorobenzene, toluene, tetrahydrofuran, dichloromethane, hexane, heptane, octane, nonane, decane, and mixtures thereof.

The application of the photosensitive composition may be performed by any coating technique, such as spin coating, dip coating, roll coating, screen coating, spray coating, spin casting, flow coating, ink jetting, vapor jetting or drop casting, but is not especially limited thereto. The film thus formed can be dried at 30-300° C., preferably 80-120° C. to evaporate the organic solvent used upon the coating before light exposure.

(iii) Three-Dimensional Microfabrication

In this step, the film of the nanocrystals is subjected to three-dimensional microfabrication by any suitable technique, such as nano-imprint lithography, microcontact printing, replica molding, microtransfer molding or microstereolithography.

The thin film is selectively exposed to electromagnetic waves through a photomask having a desired pattern. The exposure causes a crosslinking reaction between the photosensitive groups or photocurable compounds in the exposed portions to form a network of the semiconductor nanocrystals, resulting in a difference in solubility between the exposed and unexposed portions. Based on this solubility difference, development of the film with a developer enables the formation of a pattern of the semiconductor nanocrystals. The exposure may be performed by a contact or non-contact exposure process. The exposure dose is not especially limited, and can be appropriately controlled according to the thickness of the film. It is preferred that the exposure is performed at an exposure dose of 50-850 mJ/cm². When the exposure dose is lower than 50 mJ/cm², a crosslinking reaction is not likely to take place or a photo bleaching occurs, which causes poor luminescence efficiency of the patterned nanocrystals. A light source for the exposure preferably has an effective wavelength range of 200-500 nm, preferably 300-400 nm with an energy of about 100-800 W.

The exposed film is developed with a suitable developer to form a three-dimensional structure of the semiconductor nanocrystals. As the developer, there may be exemplified an organic solvent, such as toluene and chloroform, a weakly acidic solution, a weakly basic solution, or pure water.

The three-dimensional microfabrication method of example embodiments is carried out by two-photon polymerization using a laser beam. Two galvano mirrors are used to pass the focal points of the laser beam in horizontal and vertical directions through a lens having a predetermined opening ratio to photocure the photocurable material. As a result, a three-dimensional structure of the nanocrystals is formed.

According to nano-imprint lithography (NIL), a nanostructure-imprinted stamp is pressed on the surface of a resist, which is formed on a substrate by spin coating or dispensing, to transfer the nanostructure to the substrate. Specifically, a nanostructure is imprinted in a transparent stamp and an adhesion-preventing film is formed thereon. A primer layer is formed on the adhesion-preventing film. A photocurable resin is applied to a substrate and irradiated with UV light at a wavelength of 300-400 nm while pressing the stamp to cure the photocurable resin. The imprinted polymer thin film is subjected to reactive ion etching (RIE) to transfer the nanostructure to the substrate.

Another method for the formation of a three-dimensional structure using a stamp is soft lithography. Other methods are microcontact printing, replica molding, microtransfer molding, micromolding in capillaries, solvent assisted micromolding, and the like.

According to a three-dimensional microfabrication method using microstereolithography, a three-dimensional CAD model having a predetermined shape is used to construct a physical model. A three-dimensional structure formed using microstereolithography can be reduced to a few micrometers to a few hundred micrometers in size, which is difficult or impossible to achieve using conventional lithographic processes. To ensure a precision on a sub-micron level, curing phenomenon based on two-photon absorption can be utilized to form a three-dimensional structure with a precision below the diffraction limit of light. According to the curing phenomenon based on two-photon absorption, only portions having a very high peak power of laser light receive and absorb two-photon energy. Accordingly, only portions around the focal points of laser light are cured to ensure a precision on the order of 100 nm.

According to the method of example embodiments, a three-dimensional structure of light-emitting nanocrystals can be formed in which the nanocrystals are arranged in a three-dimensional array. The three-dimensional structure can be formed into photonic crystals. The three-dimensional structure can be used for the fabrication of micro-electro-mechanical systems (MEMS), thus contributing to the manufacture of display devices and electronic devices on a nanometer scale.

In a typical liquid crystal display, light is transferred through a color filter disposed on a substrate to create different colors. The color filter includes pixels, each of which includes three sub-pixels, i.e. red, green and blue sub-pixels. A black matrix surrounds the sub-pixels to provide opaque regions therebetween and prevent light leakage between thin-film transistors of the LCD.

The three-dimensional structure can be used to form red (R), green (G) and blue (B) light-emitting patterns. When a liquid crystal display is operated, the patterns simultaneously generate light of different colors in all light-emitting regions to provide color light to a display panel. Accordingly, the patterns can be used as replacements for color filters of conventional liquid crystal displays.

A UV light-emitting diode, an organic light-emitting diode (OLED), a cathode ray tube or a surface light source can be used as a light source of a backlight unit.

Example embodiments provide a display device comprising a backlight unit, a driving unit and a display unit wherein the display unit includes a three-dimensional structure of nanocrystals whose surface is coordinated with a photosensitive compound to produce two or more different colors.

A liquid crystal display (LCD) is provided with a liquid crystal panel including a plurality of liquid crystal cells arranged in a matrix form and a plurality of control switches for converting video signals to be supplied to the liquid crystal cells wherein the liquid crystal panel controls the amount of a light beam transmitted through a color filter from a backlight unit to display desired images on a screen. A liquid crystal display is a device in which when a power is applied to electrodes mounted on upper and lower glass plates, the orientation of liquid crystal molecules injected between the glass plates is varied in pixels to display images. A liquid crystal display comprises a display unit (a panel unit), a driving unit and a backlight unit. The display panel receives light of different colors from the backlight unit to display color images.

Hereinafter, example embodiments will be described in detail with reference to Examples, including Preparative Examples. These Examples are set forth to illustrate example embodiments, but should not be construed as the limit of example embodiments.

### EXAMPLES

### Preparative Example 1

### Preparation of Green Emitting CdSeS Nanocrystals Surface-Coordinated with Compound Containing Double Bond

16 g of trioctylamine (TOA), 0.5 g of oleic acid and 0.4 mmol of cadmium oxide were simultaneously put into a 125 ml flask equipped with a reflux condenser. The mixture was allowed to react with stirring while maintaining the reaction temperature at 300° C. Separately, a selenium (Se) powder was dissolved in trioctylphosphine (TOP) to obtain a Se-TOP complex solution (Se concentration: ca. 0.25 M) and a sulfur (S) powder was dissolved in TOP to obtain an S-TOP complex solution (S concentration: ca. 1.0 M). To the reaction mixture was rapidly added a mixture of the S-TOP complex solution (0.9 ml) and the Se-TOP complex solution (0.1 ml), followed by stirring for about 4 minutes. Immediately after the reaction was finished, the reaction mixture was rapidly cooled to room temperature. Ethanol as a non-solvent was added to the reaction mixture, followed by centrifugation. The precipitates were separated from the supernatant and dispersed in toluene to prepare a dispersion of CdSeS nanocrystals (1 wt %). The nanocrystals emitted light at around 520 nm, as determined by photoluminescence spectroscopy, and emitted green light under a 365 nm UV lamp.

### Preparative Example 2

### Preparation of Blue Emitting CdSeS Nanocrystals Surface-Coordinated with Compound Containing Double Bond

Blue emitting CdSeS nanocrystals were prepared in the same manner as in Preparative Example 1, except that the Se concentration of the Se-TOP complex solution was adjusted to 0.06 M and the S concentration of the S-TOP complex solution was adjusted to 2.0 M. The nanocrystals emitted light at around 480 nm, as determined by photoluminescence spectroscopy, and emitted blue light under a 365 nm UV lamp.

### Preparative Example 3

### Preparation of CdS Nanocrystals Surface-Coordinated with Compound Containing Double Bond

2.5 ml of TOA was introduced into a 25 ml flask equipped with a reflux condenser, and then the temperature was raised to 180° C. with stirring. A solution of 50 mg of cadmium dithio diethyl carbamate in 0.9 ml of TOP was rapidly added to the TOA and stirred for 10 minutes. Immediately after completion of the reaction, the reaction mixture was rapidly cooled to room temperature. Ethanol as a non-solvent was added to the reaction mixture, followed by centrifugation. The precipitates were separated from the supernatant and dispersed in toluene in the concentration of 1 wt %. Then, oleic acid was added to the dispersion until the concentration reached 5 mM. The resulting mixture was refluxed at 70° C. for 24 hours with stirring and centrifuged to obtain precipitates. The precipitates were dispersed again in toluene and oleic acid was added thereto until the concentration reached 5 mM. The mixture was refluxed at 70° C. for 24 hours with stirring. For better surface-coordination, the above procedure was repeated several times to prepare quantum dots whose surface was substituted with oleic acid. The nanocrystals were dispersed in toluene. The nanocrystals emitted light at around 510 nm, as determined by photoluminescence spectroscopy, and emitted bluish green light under a 365 nm UV lamp.

### Preparative Example 4

### Preparation of CdSeS Nanocrystals Surface-Coordinated with Compound Having Acryl Group

2 g of the toluene dispersion of the nanocrystals prepared in Preparative Example 1 was put into a 250 ml three-neck flask in an ice bath, and then 50 g of tetrahydrofuran and 0.1 g of triethylamine (TEA) were added thereto. The mixture was allowed to react with stirring under a nitrogen atmosphere for 30 minutes. To the reaction mixture was added 0.15 g of methacryloyl chloride using a dropping funnel. The reaction was continued for 4 hours. Then, adducts of salts were filtered off using a 0.1 μm filter. Thereafter, the reaction mixture was washed with 100 ml of distilled water in a separatory funnel to remove unreacted reactants and residual salts. The supernatant was separated from the reaction mixture and remaining solvents were removed in a rotary evaporator at reduced pressure of nitrogen to precipitate quantum dots. The quantum dots were again dispersed in toluene. The above procedure was repeated several times to obtain a toluene dispersion of the nanocrystals whose surface was substituted with acryl groups.

### Preparative Example 5

### Preparation of CdS Nanocrystals Surface-Coordinated with Compound Having Acryl Group

2.5 ml of TOA was introduced into a 25 ml flask equipped with a reflux condenser, and then the temperature was raised to 180° C. with stirring. A solution of 50 mg of cadmium dithio diethyl carbamate in 0.9 ml of TOP was rapidly added to the TOA and stirred for 10 minutes. Immediately after completion of the reaction, the reaction mixture was cooled to room temperature as rapidly as possible. Ethanol as a non-solvent was added to the reaction mixture, followed by centrifugation. The precipitates were separated from the supernatant and dispersed in toluene in the concentration (1 wt %).

Then, 3-mercapto-1-propanol was added to the dispersion until the concentration reached 32 mM. The resulting mixture was refluxed at room temperature for 10 hours with stirring and centrifuged to obtain quantum dots surface-coordinated with the 3-mercapto-1-propanol. The quantum dots were again dispersed in toluene in the concentration of 1 wt %. To 2 g of the dispersion were added 50 g of tetrahydrofuran and 0.1 g of triethylamine (TEA). The mixture was stirred under a nitrogen atmosphere for 30 minutes. To the reaction mixture was added dropwise 0.15 g of methacryloyl chloride using a dropping funnel. The reaction was continued for 4 hours. Then, adducts of salts were filtered off using a 0.1 μm filter. Thereafter, the reaction mixture was washed with 100 ml of distilled water in a separatory funnel to remove unreacted reactants and residual salts. The supernatant was separated from the reaction mixture and remaining solvents were removed in a rotary evaporator at reduced pressure of nitrogen to precipitate quantum dots. The quantum dots were again dispersed in toluene. The above procedure was repeated several times to obtain a toluene dispersion of the nanocrystals whose surface was substituted with acryl groups.

### Example 1

### Formation of Three-Dimensional Structure of the Green Emitting CdSeS Nanocrystals

First, a glass substrate was sufficiently washed with IPA. 0.1 g of 2,2-diethoxyacetophenone as a photocuring initiator, 0.01 g of Rhodamine B as a two-photon absorbing material and 5 g of a photocurable material (urethane acrylate, SCR 500, JSR, Japan) were thoroughly dispersed in 0.1 g of the toluene dispersion of the surface-coordinated CdSeS nanocrystals prepared in Preparative Example 1, dropped onto the glass substrate, and spin-coated at 500 rpm for 5 seconds and 3,000 rpm for 30 seconds sequentially to form a film of the semiconductor nanocrystals. Subsequently, the film was dried on a hot plate at 65° C. for one minute and baked on a hot plate at 95° C. for 15 minutes to remove the solvent.

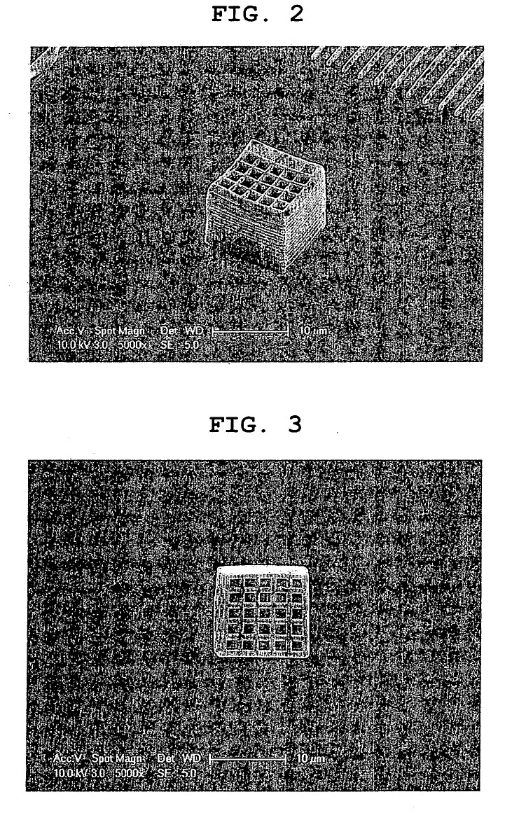

A desired three-dimensional pattern of the film was formed by irradiation with a 780-nm Ti:Sapphire laser beam. The x- and y-axis of the laser beam were controlled using a galvano scanner (resolution: 1.2 nm). Two galvano mirrors were used to pass the laser beam in horizontal and vertical directions through a lens having a predetermined opening ratio at intervals of 80 fs to photocure the photocurable material at regular rates. The control of the laser beam with respect to the z-axis direction was performed using a piezoelectric stage to allow the pattern to have an interlayer spacing of a level of 10 nm. A galvano shutter was coupled to a pin hole to adjust the irradiation time of the laser beam to a level of 1 ms. The formation procedure of the pattern was monitored using a CCD camera equipped with a high-magnification lens (1,000×). A three-dimensional shape of the pattern was constructed by successively forming voxels along the two-dimensional plane coordinates to form a layer, moving the galvano scanner by the interlayer spacing in the z-axis direction using the piezoelectric state, and repeating the above steps. At this time, the voxels were cured by two-photon polymerization of the liquid photocurable resin. The precision of the three-dimensional shape was directly affected by the individual unit voxels. Thereafter, the pattern was developed with propylene glycol methyl ether acetone (PGMEA) and cleaned with IPA to form a three-dimensional structure (FIG. 2).

### Example 2

### Formation of Three-Dimensional Structure of the CdSeS Nanocrystals

A microstructure was formed in the same manner as in Example 1, except that the green emitting CdSeS nanocrystals prepared in Preparative Example 2 were used. The microstructure is shown in FIG. 3.

### Example 3

### Formation of Three-Dimensional Structure of the CdS Nanocrystals

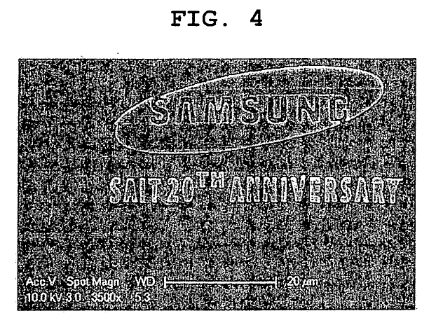

A structure was formed in the same manner as in Example 1, except that the CdS nanocrystals prepared in Preparative Example 3 were used. The structure is shown in FIG. 4.

### Example 4

### Formation of Three-Dimensional Structure of the CdSeS Nanocrystals

A structure was formed in the same manner as in Example 1, except that the CdSeS nanocrystals prepared in Preparative Example 4 were used.

### Example 5

### Formation of three-dimensional structure of the CdS nanocrystals

A structure was formed in the same manner as in Example 1, except that the CdS nanocrystals prepared in Preparative Example 5 were used.

The microfabrication method of example embodiments can be used for the fabrication of micro-electro-mechanical systems (MEMS) and nano-electro-mechanical systems (NEMS).

As is apparent from the above description, example embodiments provide a three-dimensional microfabrication method using photosensitive nanocrystals. The method of example embodiments enables the formation of a three-dimensional structure of light-emitting nanocrystals with high precision in a relatively simple manner. Nanocrystals surface-coordinated with a photosensitive compound used in the method of example embodiments can be formed into photonic crystals. When the photonic crystals are irradiated with light to chemically emit fluorescence in an effective manner, the luminescence efficiency is further increased due to the physical three-dimensional structure of the nanocrystals, thus achieving high color reproduction efficiency when compared to conventional color filters. Therefore, the three-dimensional structure of nanocrystals can be used for the fabrication of a variety of devices, including liquid crystal display devices, with improved luminance at reduced power consumption.

Example embodiments also provide a display device comprising the three-dimensional structure of nanocrystals. Since the display device of example embodiments realizes high luminance, it can be used to manufacture a liquid crystal display with markedly improved luminance.

Although example embodiments have been disclosed for illustrative purposes, those skilled in the art will appreciate that various modifications, additions and substitutions are possible, without departing from the scope and spirit of the accompanying claims.

What is claimed is:

1. A three-dimensional microfabrication method using photosensitive nanocrystals, the method comprising the steps of:
preparing a photosensitive composition comprising a photocurable compound and nanocrystals whose surface is coordinated with a compound having a photosensitive group;
applying the photosensitive composition to a substrate to form a thin film; and
subjecting the thin film to three-dimensional microfabrication.

2. The method according to claim 1, wherein the three-dimensional microfabrication step is carried out by nano-imprint lithography, microcontact printing, replica molding, microtransfer molding or microstereolithography.

3. The method according to claim 2, wherein the microstereolithography uses two-photon absorption.

4. The method according to claim 1, wherein the photosensitive composition is applied by spin coating, dip coating, roll coating, screen coating, spray coating, spin casting, flow coating, screen printing, ink jetting or drop casting.

5. The method according to claim 1, wherein the nanocrystals are semiconductor nanocrystals selected from the group consisting of Group II-VI, Group III-V, Group IV-VI, Group IV compounds, and mixtures thereof.

6. The method according to claim 1, wherein the nanocrystals are metal oxide nanocrystals selected from the group consisting of TiO₂, ZnO, SiO₂, SnO₂, WO₃, Ta₂O₃, BaTiO₃, BaZrO₃, ZrO₂, HfO₂, Al₂O₃, Y₂O₃, ZrSiO₄ and mixtures thereof.

7. The method according to claim 1, wherein the compound having a photosensitive group is represented by Formula 1:
X-A-B (1)
wherein X is NC—, HOOC—, HRN—, POOOH—, RS— or RSS— (in which R is hydrogen or a C₁-C₁₀ saturated or unsaturated aliphatic hydrocarbon group); A is a direct bond, an aliphatic organic group, a phenylene group or a biphenylene group; and B is an organic group containing one or more carbon-carbon double bonds which is interrupted or terminated by at least one group selected from —CN, —COOH, halogen groups, C₁-C₅ halogenated alkyl groups, amine groups, C₆-C₁₅ aromatic hydrocarbon groups, and C₆-C₁₂ aromatic hydrocarbon groups substituted with F, Cl, Br, a halogenated alkyl group, R′O— (in which R′ is hydrogen or C₁-C₅ alkyl), —COOH, an amine group or —NO₂.

8. The method according to claim 7, wherein the aliphatic organic group of A in Formula 1 is a saturated aliphatic hydrocarbon group, an aliphatic ester group, an aliphatic amide group, an aliphatic oxycarbonyl group or an aliphatic ether group.

9. The method according to claim 7, wherein B in Formula 1 is an organic group represented by Formula 2:
—CR₁═CR₂R₃ (2)
wherein R₁ is hydrogen, —COOH, a halogen group, a C₁-C₅ alkyl group or a halogenated alkyl group; and R₂ and R₃ are each independently hydrogen, a C₁-C₃₀ alkyl group, —CN, —COOH, a halogen group, a C₁-C₅ halogenated alkyl group, a C₂-C₃₀ unsaturated aliphatic hydrocarbon group containing one or more carbon-carbon double bonds, or a C₆-C₁₂ aromatic hydrocarbon group substituted or unsubstituted with at least one group selected from F, Cl, Br, hydroxyl, C₁-C₅ halogenated alkyl groups, amine groups, R′O— (in which R′ is C₁-C₅ alkyl), —COOH and —NO₂.

10. The method according to claim 7, wherein the compound having a photosensitive group is selected from the group consisting of acrylic acids, unsaturated fatty acids, cinnamic acids, vinyl benzoic acids, acrylonitrile compounds, unsaturated nitrile compounds, unsaturated amine compounds, unsaturated sulfide compounds, and mixtures thereof.

11. The method according to claim 1, wherein the photocurable compound is selected from the group consisting of polymers, ester compounds and ether compounds having at least one acryl and/or vinyl group, and mixtures thereof.

12. The method according to claim 11, wherein the photocurable compound is a polyfunctional acrylate or polyalkylene oxide compound having two or more acryl and/or vinyl groups, or is selected from the group consisting of polysiloxane polymers having one or more acryl and/or vinyl groups and mixtures thereof.

13. The method according to claim 11, wherein the photocurable compound is selected from the group consisting of allyloxylated cyclohexyl diacrylate, bis(acryloxyethyl)hydroxy isocyanurate, bis(acryloxyneopentyl glycol)adipate, bisphenol A diacrylate, bisphenol A dimethacrylate, 1,4-butanediol diacrylate, 1,4-butanediol dimethacrylate, 1,3-butylene glycol diacrylate, 1,3-butylene glycol dimethacrylate, dicyclopentanyl diacrylate, diethylene glycol diacrylate, diethylene glycol dimethacrylate, dipentaerythritol hexaacrylate, dipentaerythritol monohydroxypentacrylate, ditrimethylolpropane tetraacrylate, ethylene glycol dimethacrylate, glycerol methacrylate, 1,6-hexanediol diacrylate, neopentyl glycol dimethacrylate, neopentyl glycol hydroxypivalate diacrylate, pentaerythritol triacrylate, pentaerythritol tetraacrylate, phosphoric acid dimethacrylate, polyethylene glycol diacrylate, polypropylene glycol diacrylate, tetraethylene glycol diacrylate, tetrabromobisphenol A diacrylate, triethylene glycol divinyl ether, triglycerol diacrylate, trimethylolpropane triacrylate, tripropylene glycol diacrylate, tris(acryloxyethyl)isocyanurate, phosphoric acid triacrylate, phosphoric acid diacrylate, acrylic acid propargyl ester, vinyl terminated polydimethylsiloxane, vinyl terminated diphenylsiloxane-dimethylsiloxane copolymer, vinyl terminated polyphenylmethylsiloxane, vinyl terminated trifluoromethylsiloxane-dimethylsiloxane copolymer, vinyl terminated diethylsiloxane-dimethylsiloxane copolymer, vinylmethylsiloxane, monomethacryloyloxypropyl terminated polydimethyl siloxane, monovinyl terminated polydimethyl siloxane, monoallyl-monotrimethylsiloxy terminated polyethylene oxide, and mixtures thereof.

14. The method according to claim 12, wherein the photosensitive composition further comprises a photoinitiator and a two-photon absorbing compound.

15. The method according to claim 14, wherein the two-photon absorbing compound is selected from the group consisting of the following compounds (3):

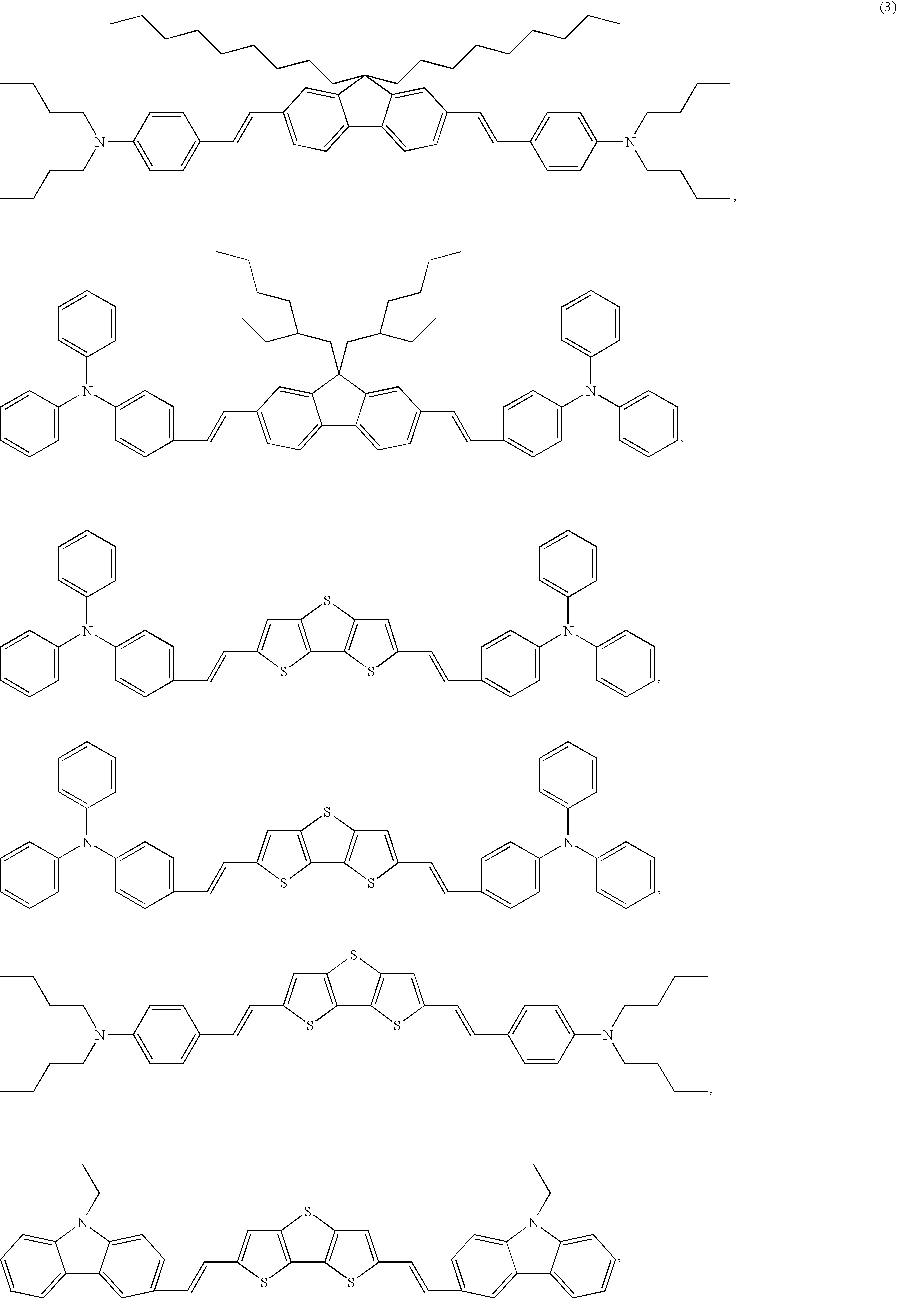

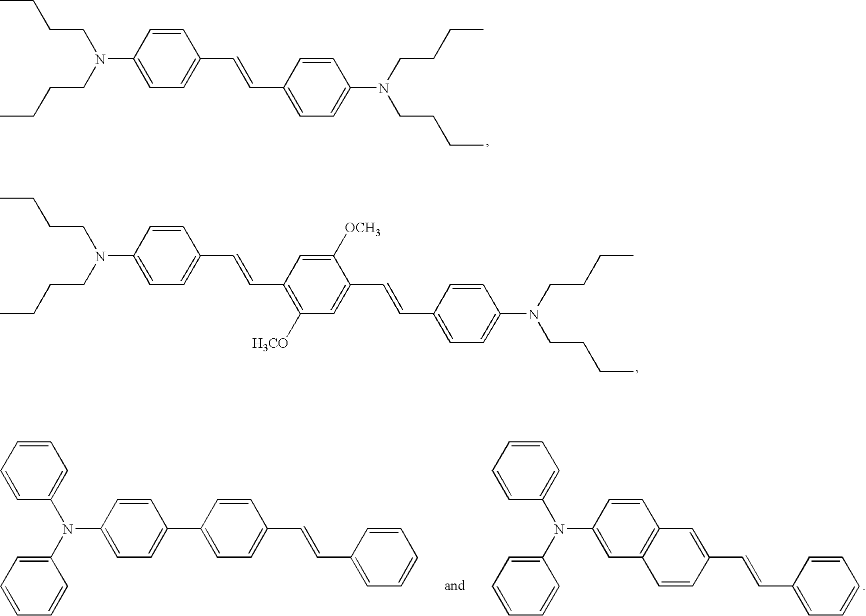

16. A display device comprising a display unit and a backlight unit wherein the display unit includes a light-emitting layer composed of a three-dimensional structure of nanocrystals whose surface is coordinated with a photosensitive compound to produce two or more different colors.

17. The display device according to claim 16, wherein the photosensitive compound is represented by Formula 1:
X-A-B (1)
wherein X is NC—, HOOC—, HRN—, POOOH—, RS— or RSS— (in which R is hydrogen or a C₁-C₁₀ saturated or unsaturated aliphatic hydrocarbon group); A is a direct bond, an aliphatic organic group, a phenylene group or a biphenylene group; and B is an organic group containing one or more carbon-carbon double bonds which is interrupted or terminated by at least one group selected from —CN, —COOH, halogen groups, C₁-C₅ halogenated alkyl groups, amine groups, C₆-C₁₅ aromatic hydrocarbon groups, and C₆-C₁₂ aromatic hydrocarbon groups substituted with F, Cl, Br, a halogenated alkyl group, R′O— (in which R′ is hydrogen or C₁-C₅ alkyl), —COOH, an amine group or —NO₂.

18. The display device according to claim 17, wherein the aliphatic organic group of A in Formula 1 is a saturated aliphatic hydrocarbon group, an aliphatic ester group, an aliphatic amide group, an aliphatic oxycarbonyl group or an aliphatic ether group.

19. The display device according to claim 17, wherein B in Formula 1 is an organic group represented by Formula 2:
—CR₁═CR₂R₃ (2)
wherein R₁ is hydrogen, —COOH, a halogen group, a C₁-C₅ alkyl group or a halogenated alkyl group; and R₂ and R₃ are each independently hydrogen, a C₁-C₃₀ alkyl group, —CN, —COOH, a halogen group, a C₁-C₅ halogenated alkyl group, a C₂-C₃₀ unsaturated aliphatic hydrocarbon group containing one or more carbon-carbon double bonds, or a C₆-C₁₂ aromatic hydrocarbon group substituted or unsubstituted with at least one group selected from F, Cl, Br, hydroxyl, C₁-C₅ halogenated alkyl groups, amine groups, R′O— (in which R′ is C₁-C₅ alkyl), —COOH and —NO₂.

20. A display device comprising the backlight unit of the display device according to claim 16, a driving unit and a liquid crystal module.
